(19) United States
(12) Patent Application Publication
(10) Pub. No.: US 2025/0047029 A1
(43) Pub. Date: Feb. 6, 2025

(54) CONNECTOR AND DISK DEVICE

(71) Applicants: Kabushiki Kaisha Toshiba, Tokyo (JP); Toshiba Electronic Devices & Storage Corporation, Tokyo (JP)

(72) Inventors: Hayato YAMAGUCHI, Yokohama Kanagawa (JP); Nobuhiro YAMAMOTO, Yokohama Kanagawa (JP); Taichi OKANO, Yokohama Kanagawa (JP); Masahide TAKAZAWA, Hachioji Tokyo (JP)

(21) Appl. No.: 18/597,080

(22) Filed: Mar. 6, 2024

(30) Foreign Application Priority Data
Jul. 31, 2023 (JP) 2023-124355

(51) Int. Cl. H01R 13/502; H01R 12/71; H01R 13/04

(52) U.S. Cl. CPC H01R 13/502; H01R 12/716; H01R 13/04

(57) ABSTRACT

According to one embodiment, a connector includes a housing and a plurality of leads. The housing has a first surface and a second surface opposite the first surface. The housing is provided with a through hole opening to the first surface and the second surface. Each of the plurality of leads includes a first terminal accommodated in the through hole.

### CROSS-REFERENCE TO RELATED APPLICATIONS

This application is based upon and claims the benefit of priority from Japanese Patent Application No. 2023-124355, filed on Jul. 31, 2023; the entire contents of which are incorporated herein by reference.

### FIELD

Embodiments described herein relate generally to a connector and a disk device.

### BACKGROUND

A connector serves to electrically connect two components to each other. For example, in a disk device such as a hard disk drive, a connector is mounted on a substrate such as a flexible printed circuit board that electrically connects a controller to magnetic heads.

There is a possibility that substances such as flux contaminate a device such as a disk device incorporating a connector. Such contaminants may be removed from the device by cleaning. The contaminants may, however, still remain in the device, for example, inside the connector or in a gap between the connector and the substrate.

### BRIEF DESCRIPTION OF THE DRAWINGS

FIG. 1 is an exemplary perspective view illustrating an HDD according to a first embodiment in an exploded manner;

FIG. 2 is an exemplary plan view schematically illustrating an FPC of the first embodiment;

FIG. 3 is an exemplary perspective view illustrating a relay connector of the first embodiment;

FIG. 4 is an exemplary plan view illustrating the relay connector of the first embodiment;

FIG. 5 is an exemplary cross-sectional view of the FPC and the relay connector of the first embodiment taken along line F5-F5 in FIG. 4;

FIG. 6 is an exemplary perspective view illustrating a relay connector according to a second embodiment;

FIG. 7 is an exemplary plan view illustrating the relay connector of the second embodiment;

FIG. 8 is an exemplary cross-sectional view of an FPC and the relay connector of the second embodiment taken along line F8-F8 in FIG. 7;

FIG. 9 is an exemplary cross-sectional view illustrating an FPC and a relay connector according to a third embodiment;

FIG. 10 is an exemplary plan view illustrating a relay connector according to a fourth embodiment;

FIG. 11 is an exemplary perspective view illustrating a relay connector according to a fifth embodiment; and

FIG. 12 is an exemplary cross-sectional view illustrating the relay connector of the fifth embodiment.

### DETAILED DESCRIPTION

In general, according to one embodiment, a connector includes a housing and a plurality of leads. The housing has a first surface and a second surface opposite the first surface. The housing is provided with a through hole opening to the first surface and the second surface. Each of the plurality of leads includes a first terminal accommodated in the through hole.

### First Embodiment

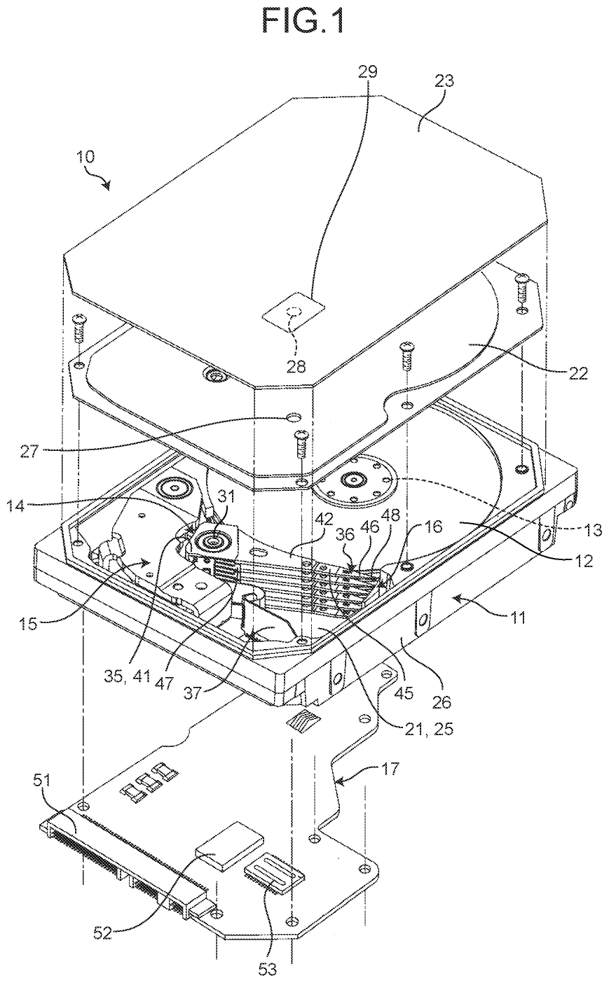

Hereinafter, a first embodiment will be described with reference to FIGS. 1 to 5. It is noted that, in the present specification, components according to embodiments and descriptions of the components may be described in a plurality of expressions. The components and the description thereof are examples, and are not limited by the expression of the present specification. Components may also be identified with names different from those described in the present specification. In addition, the components may be described by expressions different from the expressions in the present specification.

In the following description, “prevent” is defined as, for example, preventing occurrence of an event, an action, or an influence, or reducing a degree of the event, the action, or the influence.

FIG. 1 is an exemplary perspective view illustrating a hard disk drive (HDD) 10 according to the first embodiment in an exploded manner. The HDD 10 is an example of a disk device, and may also be referred to as an electronic device, a storage device, an external storage device, or a magnetic disk device. It is noted that the disk device is not limited to the HDD 10.

As illustrated in FIG. 1, the HDD 10 includes a case 11, a plurality of magnetic disks 12, a spindle motor 13, a head stack assembly (HSA) 14, a voice coil motor (VCM) 15, a ramp load mechanism 16, and a printed circuit board (PCB) 17. The magnetic disk 12 may also be referred to as a disk, a medium, or a platter.

The case 11 includes a base 21, an inner cover 22, and an outer cover 23. It is noted that the case 11 is not limited to this example. Each of the base 21, the inner cover 22, and the outer cover 23 is made of a metal material such as an aluminum alloy. It is noted that the materials of the base 21, the inner cover 22, and the outer cover 23 may be different from each other.

The base 21 is formed in a substantially rectangular parallelepiped box shape opened in one direction. The base 21 accommodates the plurality of magnetic disks 12, the spindle motor 13, the HSA 14, the VCM 15, and the ramp load mechanism 16.

The base 21 has a bottom wall 25 and a side wall 26. The bottom wall 25 is formed in a substantially rectangular (quadrangular) plate shape. The side wall 26 protrudes from an edge of the bottom wall 25 and is formed in a substantially rectangular frame shape.

The inner cover 22 is mounted on an end portion of the side wall 26 with, for example, a screw, and closes the base 21. The outer cover 23 covers the inner cover 22 and is mounted on the end portion of the side wall 26 by, for example, welding.

A vent hole 27 is provided in the inner cover 22. Furthermore, the outer cover 23 is provided with a vent hole 28. After components are mounted on the inside of the base 21, and the inner cover 22 and the outer cover 23 are mounted on the base 21, air inside the case 11 is removed from the vent holes 27 and 28. Furthermore, the inside of the case 11 is filled with gas different from air.

The gas filled inside the case 11 is, for example, a low density gas having a density lower than that of air, an inert gas having low reactivity, or the like. For example, helium is filled inside the case 11. It is noted that the inside of the case 11 may be filled with another fluid. The inside of the case 11 may be maintained at vacuum, low pressure close to vacuum, or negative pressure lower than atmospheric pressure.

The vent hole 28 of the outer cover 23 is closed by a seal 29. The seal 29 airtightly seals the vent hole 28 and restricts fluid filling the case 11 from leaking from the vent hole 28 to the outside of the case 11.

The plurality of magnetic disks 12 are formed in a disk shape arranged substantially parallel to the bottom wall. The plurality of magnetic disks 12 are arranged at intervals. The HDD 10 according to the present embodiment includes, for example, ten or more magnetic disks 12. It is noted that the number of magnetic disks 12 is not limited to this example.

The spindle motor 13 supports the plurality of magnetic disks 12. The plurality of magnetic disks 12 are held by a hub of the spindle motor 13 by, for example, a clamp spring. The spindle motor 13 rotates the plurality of magnetic disks 12.

The case 11 is provided with a support shaft 31 separated from the magnetic disk 12. For example, the support shaft 31 extends from the bottom wall 25 of the case 11. The HSA 14 is rotatably supported by the support shaft 31.

The HSA 14 has a carriage 35, a plurality of head gimbal assemblies (HGA) 36, and a flexible printed circuit board (FPC) 37. The FPC is an example of a substrate. The carriage 35 includes an actuator block 41 and a plurality of arms 42.

The actuator block 41 and the plurality of arms 42 are integrally formed of, for example, aluminum and an alloy. It is noted that the materials of the actuator block 41 and the arm 42 are not limited to this example.

The actuator block 41 is supported by, for example, the support shaft 31 via a bearing so as to be rotatable around the support shaft 31. The plurality of arms 42 protrude substantially in parallel from the actuator block 41.

The plurality of arms 42 are arranged at intervals. Each of the plurality of arms 42 can enter a gap between two adjacent magnetic disks 12 among the plurality of magnetic disks 12.

The VCM 15 includes a voice coil mounted on the carriage 35, a pair of yokes, and magnets provided on the yokes. The VCM 15 rotates the carriage 35 around the support shaft 31.

The HGA 36 includes a base plate 45, a load beam 46, a flexure 47, and a magnetic head 48. The base plate 45 is mounted on the tip of the arm 42. The load beam 46 is formed to be thinner than the base plate 45 and extends from the base plate 45.

The flexure 47 is formed in an elongated belt shape. It is noted that the shape of the flexure 47 is not limited to this example. The flexure 47 is a kind of flexible printed circuit board (FPC) including a metal plate (backing layer) made of stainless steel or the like, an insulating layer (base layer) formed on the metal plate, a conductive layer formed on the insulating layer and configured to form a plurality of wirings (wiring patterns), and an insulating layer (cover layer) covering the conductive layer.

A gimbal unit (elastic support unit) which is located on the load beam 46 and is displaceable is provided at one end portion of the flexure 47. The magnetic head 48 is mounted on the gimbal unit of the flexure 47. The magnetic head 48 records and reproduces information on a recording layer of the magnetic disk 12. In other words, the magnetic head 48 reads and writes information from and to the magnetic disk 12.

The VCM 15 rotates the carriage 35 to arrange the magnetic head 48 at a desired location on the magnetic disk 12. When the magnetic head 48 moves to the outermost periphery of the magnetic disk 12, the ramp load mechanism 16 holds the magnetic head 48 at an unload location separated from the magnetic disk 12.

The FPC 37 is connected to the other end portion of the flexure 47. For example, a plurality of flexures 47 are connected to the FPC 37. Thus, the FPC 37 is electrically connected to the plurality of magnetic heads 48 via the wirings of the plurality of flexures 47.

The PCB 17 is, for example, a rigid substrate such as a glass epoxy substrate, and is a multilayer substrate or a build-up substrate. The PCB 17 is disposed outside the case 11 and is mounted on the bottom wall 25 of the base 21. The PCB 17 is mounted on the bottom wall 25 by, for example, a plurality of screws.

The HDD 10 further includes, for example, an interface (I/F) connector 51, a controller 52, and a relay connector 53. The I/F connector 51, the controller 52, and the relay connector 53 are mounted on the PCB 17. In addition, other components may be mounted on the PCB 17.

The I/F connector 51 is a connector conforming to an interface standard such as Serial ATA (SATA), and is connected to an I/F connector of a host computer. The controller 52 is, for example, a system-on-chip (SoC), and includes a read/write channel (RWC), a hard disk controller (HDC), and a processor.

The relay connector 53 is electrically connected to various components arranged inside the case 11, for example, through a connector provided on the bottom wall 25. As a result, the PCB 17 is electrically connected to the spindle motor 13, the VCM 15, the FPC 37, and the magnetic head 48 disposed inside the case 11.

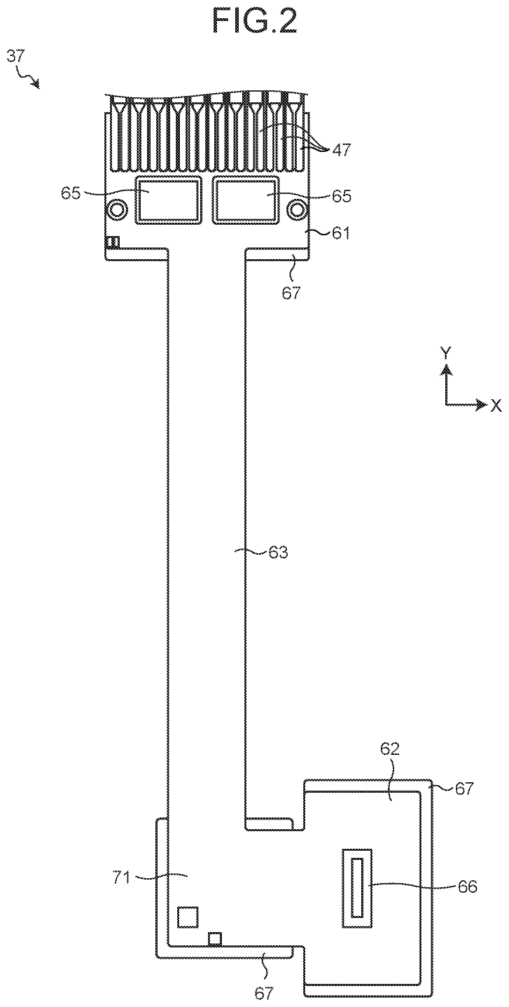

FIG. 2 is an exemplary plan view schematically illustrating the FPC 37 of the first embodiment. As illustrated in FIG. 2, the FPC 37 is detached from other components and is formed in a substantially L-shaped belt shape in a natural state in which no external force acts. It is noted that the shape of the FPC 37 is not limited to this example. The FPC 37 includes a first connection portion 61, a second connection portion 62, and an intermediate portion 63.

The first connection portion 61 is provided, for example, at one end portion of the FPC 37 in the direction in which the FPC 37 extends. The first connection portion 61 is mounted on the actuator block 41 by, for example, a screw. The first connection portion 61 is electrically connected to the flexure 47.

The second connection portion 62 is provided, for example, at the other end portion of the FPC 37 in the direction in which the FPC 37 extends. The second connection portion 62 is mounted on the bottom wall 25 by, for example, a screw. The second connection portion 62 is electrically connected to the relay connector 53 through, for example, a connector provided on the bottom wall 25.

The intermediate portion 63 is provided between the first connection portion 61 and the second connection portion 62. The intermediate portion 63 extends in a belt shape and bends between the first connection portion 61 and the second connection portion 62 in accordance with rotation of the actuator block 41.

As illustrated in the drawings, in the present specification, an X axis, a Y axis, and a Z axis are defined for convenience. The X axis, the Y axis, and the Z axis are orthogonal to each other. The X axis is provided along the width of the intermediate portion 63 in the natural state. The Y axis is provided along the length of the intermediate portion 63 in the natural state. The Z axis is provided along the thickness of the FPC 37 in the natural state.

Furthermore, in the present specification, an X direction, a Y direction, and a Z direction are defined. The X direction is a direction along the X axis and includes a +X direction indicated by an arrow of the X axis and a −X direction which is an opposite direction of the arrow of the X axis. The Y direction is a direction along the Y axis, and includes a +Y direction indicated by an arrow of the Y axis and a −Y direction which is an opposite direction of the arrow of the Y axis. The Z direction is a direction along the Z axis and includes a +Z direction indicated by an arrow of the Z axis and a −Z direction which is an opposite direction of the arrow of the Z axis.

The first connection portion 61 is connected to an end portion of the intermediate portion 63 in the +Y direction and extends in the +Y direction from the end portion. The second connection portion 62 is connected to the end portion of the intermediate portion 63 in the −Y direction and extends in the +X direction from the end portion. It is noted that the first connection portion 61 and the second connection portion 62 are not limited to this example.

The HDD 10 further includes a plurality of preamplifiers 65, a relay connector 66, and a plurality of reinforcing plates 67. The relay connector 66 is an example of a connector. The preamplifier 65 and the relay connector 66 are mounted on the FPC 37.

The preamplifier 65 is mounted on the first connection portion 61. The preamplifier 65 is electrically connected to the flexure 47 via, for example, wiring and pads of the FPC 37. The preamplifier 65 amplifies a write signal, transmits the write signal to the magnetic head 48, and amplifies a read signal received from the magnetic head 48.

The relay connector 66 is mounted on the second connection portion 62. The relay connector 66 is electrically connected to the relay connector 53 through, for example, the connector provided on the bottom wall 25. The second connection portion 62 is thereby electrically connected to the PCB 17. It is noted that the relay connector 66 may be directly connected to the relay connector 53.

The reinforcing plate 67 is made of, for example, metal such as aluminum or synthetic resin, and is formed in a plate shape. It is noted that the reinforcing plate 67 is not limited to this example. The plurality of reinforcing plates 67 are mounted on the first connection portion 61 and the second connection portion 62.

The reinforcing plate 67 has higher rigidity than that of the FPC 37. For this reason, the reinforcing plate 67 improves rigidity of the first connection portion 61 and the second connection portion 62. The intermediate portion 63 is not mounted on the reinforcing plate 67 and can be bent.

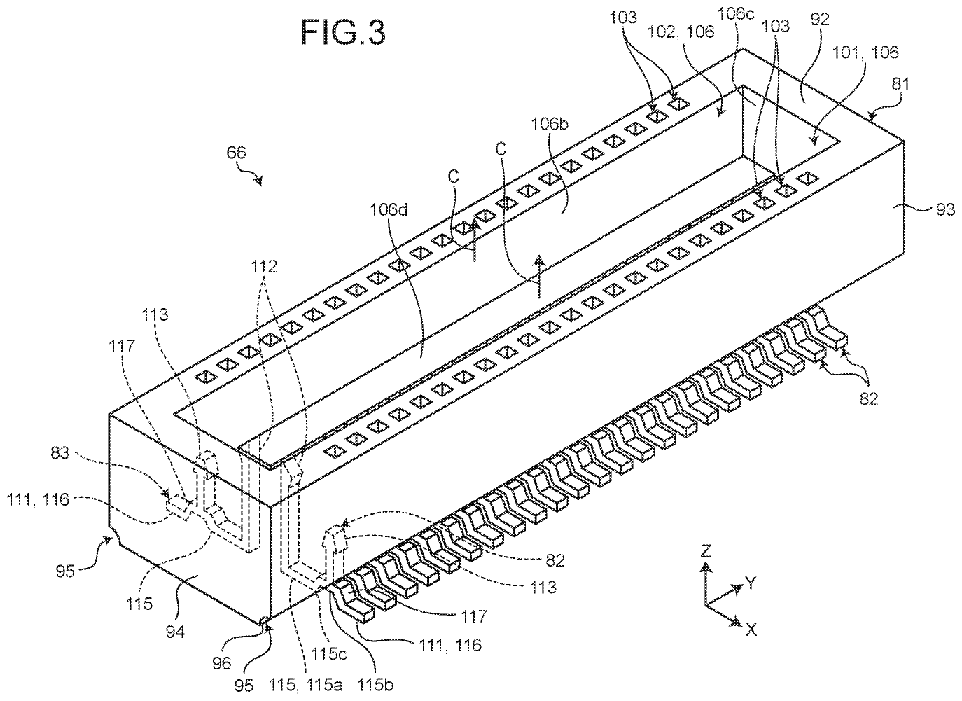

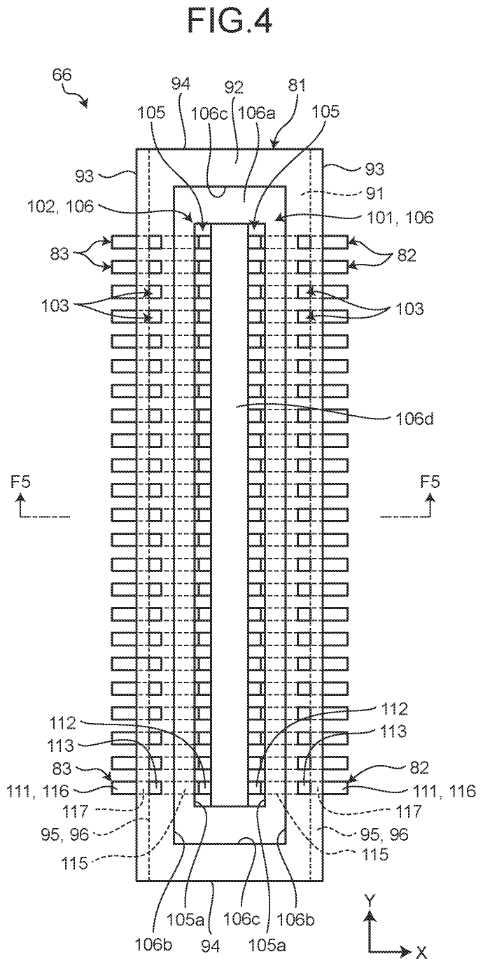

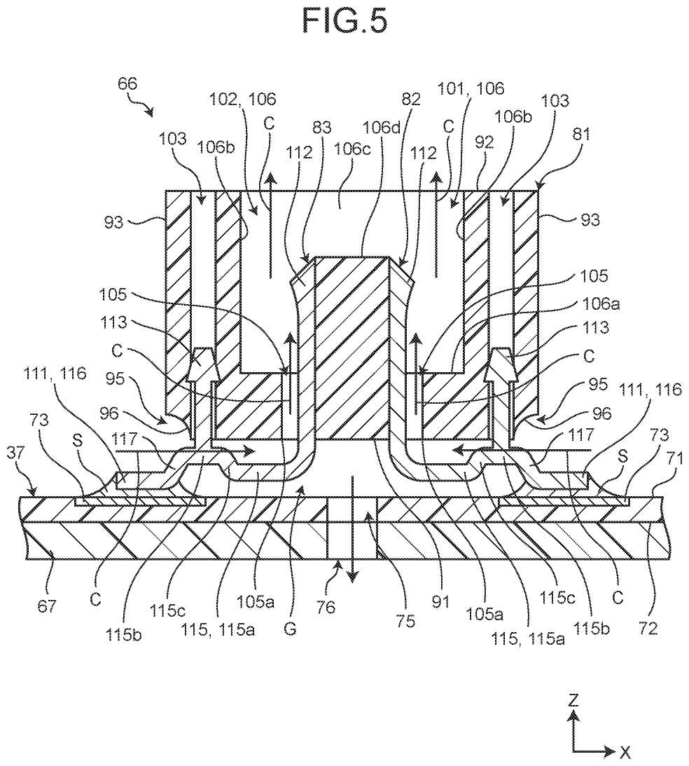

FIG. 3 is an exemplary perspective view illustrating the relay connector 66 of the first embodiment. FIG. 4 is an exemplary plan view illustrating the relay connector 66 of the first embodiment. FIG. 5 is an exemplary cross-sectional view of the FPC 37 and the relay connector 66 of the first embodiment taken along line F5-F5 in FIG. 4.

As illustrated in FIG. 5, the FPC 37 includes a mounting surface 71, a back surface 72, and a plurality of pads 73. The pad 73 may also be referred to as a land or an electrode. The mounting surface 71 is one surface of the FPC 37 and faces substantially in the +Z direction. The back surface 72 is located on the opposite side of the mounting surface 71 and is mounted on the reinforcing plate 67.

The plurality of pads 73 are provided on the mounting surface 71. The mounting surface 71 is formed by, for example, a part of the conductive layer forming the plurality of pads 73 and an insulating cover layer partially covering the conductive layer. It is noted that the mounting surface 71 is not limited to this example. For example, the plurality of pads 73 are arranged in two rows in the Y direction.

At least one of the plurality of pads 73 is electrically connected to the preamplifier 65 via wiring of the conductive layer. It is noted that the pad 73 is not limited to this example. For example, at least one of the plurality of pads 73 may be electrically connected to the VCM 15 or a ground plane.

A hole 75 is provided in the FPC 37. The hole 75 is located between the plurality of pads 73 forming one row and the plurality of pads 73 forming the other row in the X direction. The hole 75 penetrates the FPC 37 and is open to the mounting surface 71 and the back surface 72. The reinforcing plate 67 is also provided with a hole 76. The hole 76 penetrates the reinforcing plate 67 and communicates with the hole 75 of the FPC 37.

The relay connector 66 includes a housing 81 and a plurality of leads 82 and 83. The leads 82 and 83 may also be referred to as terminals. In the present embodiment, the lead 82 is a specific example of the lead. It is noted that the lead 83 may be a specific example of the lead.

The housing 81 is made of, for example, synthetic resin. The housing 81 is formed in a substantially rectangular parallelepiped shape extending in the Y direction. That is, the Y direction is the longitudinal direction of the housing 81. It is noted that the shape of the housing 81 is not limited to this example.

The housing 81 has a lower surface 91, an upper surface 92, and two side surfaces 93 illustrated in FIG. 5, and two end surfaces 94 illustrated in FIG. 4. The lower surface 91 is an example of a first surface. The upper surface 92 is an example of a second surface. The side surfaces 93 are examples of a third surface and a fourth surface. The end surface 94 is an example of a fifth surface.

Each of the lower surface 91, the upper surface 92, and the two side surfaces 93 is formed in a substantially rectangular shape extending in the Y direction which is the longitudinal direction. It is noted that the shapes of the lower surface 91, the upper surface 92, and the side surfaces 93 are not limited to this example.

As illustrated in FIG. 5, the lower surface 91 is formed to be substantially flat and faces substantially in the −Z direction. It is noted that the lower surface 91 may be provided with irregularities. The lower surface 91 of the housing 81 and the mounting surface 71 of the FPC 37 face each other with a gap G interposed therebetween. Further, the lower surface 91 faces the hole 75 of the FPC 37.

The upper surface 92 is located on the opposite side of the lower surface 91. The upper surface 92 is more separated from the FPC 37 than the lower surface 91. The upper surface 92 is formed to be substantially flat and faces substantially in the +Z direction. In the X direction, the length (width) of the upper surface 92 is larger than the length (width) of the lower surface 91. It is noted that the widths of the lower surface 91 and the upper surface 92 are not limited to this example.

The two side surfaces 93 are provided at the opposite ends of the housing 81 in the X direction. The two side surfaces 93 extend substantially in the −Z direction from the opposite ends of the upper surface 92 in the X direction. The two side surfaces 93 are formed to be substantially flat.

One side surface 93 faces substantially in the +X direction. The other side surface 93 faces substantially in the −X direction. That is, the side surface 93 faces a direction different from the −Z direction that the lower surface 91 faces. It is noted that the side surface 93 may face a direction different from the X direction.

A cutout 95 is provided at a corner between the lower surface 91 and the side surface 93. In other words, the lower surface 91 and the side surface 93 are connected to each other via the cutout 95. Therefore, the side surface 93 is provided between the lower surface 91 and the upper surface 92. In the present embodiment, the cutout 95 is provided in substantially the entire area of the corner between the lower surface 91 and the side surface 93, and extends in the Y direction. It is noted that the cutout 95 may be provided at a part of the corner between the lower surface 91 and the side surface 93.

The cutout 95 is recessed in an arc shape toward the inside of the housing 81. By providing the cutout 95, a concave surface 96, which is a substantially cylindrical curved surface recessed toward the inside of the housing 81, is provided between the end of the lower surface 91 in the X direction and the end of the side surface 93 in the −Z direction. The concave surface 96 forms (regulation, section) the cutout 95.

The cutout 95 and the concave surface 96 are not limited to the above-described example. For example, the concave surface 96 may be a surface (chamfer) extending obliquely relative to the lower surface 91 and the side surface 93, or may be a substantially cylindrical curved surface protruding toward the outside of the housing 81.

As illustrated in FIG. 4, the two end surfaces 94 are provided at the opposite ends of the housing 81 in the Y direction. The two end surfaces 94 are formed to be substantially flat. One end surface 94 faces substantially in the +Y direction. The other end surface 94 faces substantially in the −Y direction.

As illustrated in FIG. 5, the housing 81 is provided with two through holes 101 and 102 and a plurality of fixing holes 103. In the present embodiment, the through hole 101 is a specific example of the through hole. It is noted that the through hole 102 may be a specific example of the through hole.

The two through holes 101 and 102 are adjacent to each other in the X direction and are formed in mirror symmetry with each other. Each of the two through holes 101 and 102 includes a pin insertion portion 105 and a connector insertion portion 106.

The pin insertion portion 105 is open to the lower surface 91. The pin insertion portion 105 extends, for example, substantially in the +Z direction from the lower surface 91. The connector insertion portion 106 is open to the upper surface 92. The connector insertion portion 106 extends, for example, substantially in the −Z direction from the upper surface 92.

An end of the pin insertion portion 105 in the +Z direction and an end of the connector insertion portion 106 in the −Z direction are connected to each other. Thus, each of the through holes 101 and 102 penetrates the housing 81 so as to be open to the lower surface 91 and the upper surface 92.

Each of the pin insertion portion 105 and the connector insertion portion 106 extends in the Y direction. In other words, the length of the pin insertion portion 105 in each of the X direction and the Z direction is shorter than the length of the pin insertion portion 105 in the Y direction. Further, the length of the connector insertion portion 106 in each of the X direction and the Z direction is shorter than the length of the connector insertion portion 106 in the Y direction.

The housing 81 further includes a bottom surface 106a, two inner side surfaces 106b, two inner end surfaces 106c, and a protrusion 106d. The bottom surface 106a, the two inner side surfaces 106b, the two inner end surfaces 106c, and the protrusion 106d form (regulation, section) the connector insertion portions 106 of the two through holes 101 and 102.

The bottom surface 106a is provided at an end portion of the connector insertion portion 106 in the −Z direction. The bottom surface 106a is located between the lower surface 91 and the upper surface 92 in the Z direction. The bottom surface 106a is formed to be substantially flat and faces substantially in the +Z direction.

The two inner side surfaces 106b extend substantially in the +Z direction from the opposite ends of the bottom surface 106a in the X direction. The one inner side surface 106b is provided at an end portion of the connector insertion portion 106 in the +X direction and faces substantially in the −X direction. The other inner side surface 106b is provided at an end portion of the connector insertion portion 106 in the −X direction and faces substantially in the +X direction. The two inner side surfaces 106b face each other.

The two inner end surfaces 106c extend substantially in the +Z direction from the opposite ends of the bottom surface 106a in the Y direction. The one inner end surface 106c is provided at an end portion of the connector insertion portion 106 in the +Y direction and faces substantially in the −Y direction. The other inner end surface 106c is provided at an end portion of the connector insertion portion 106 in the −Y direction and faces substantially in the +Y direction. The two inner end surfaces 106c face each other.

The protrusion 106d protrudes substantially in the +Z direction from the bottom surface 106a at a location separated from the two inner side surfaces 106b and the two inner end surfaces 106c. An end portion of the protrusion 106d in the +Z direction is located between the lower surface 91 and the upper surface 92 in the Z direction. It is noted that the end portion of the protrusion 106d in the +Z direction may be at the same location as the upper surface 92 in the Z direction, or may be more separated from the lower surface 91 than the upper surface 92.

The connector insertion portion 106 of the through hole 101 is formed (regulation, section) by the bottom surface 106a, one inner side surface 106b, the two inner end surfaces 106c, and the protrusion 106d. The connector insertion portion 106 of the through hole 102 is formed by the bottom surface 106a, the other inner side surface 106b, the two inner end surfaces 106c, and the protrusion 106d.

The connector insertion portions 106 of the two through holes 101 and 102 communicate with each other between the inner end surface 106c and the protrusion 106d. Further, the connector insertion portions 106 of the two through holes 101 and 102 also communicate with each other between the upper surface 92 and the protrusion 106d. It is noted that the two through holes 101 and 102 may be separated from each other.

The pin insertion portion 105 is open to the bottom surface 106a. A cross-sectional area of the pin insertion portion 105 that is open to the bottom surface 106a is smaller than that of the bottom surface 106a. It is noted that the cross-sectional area of the pin insertion portion 105 and the size of the bottom surface 106a may be set to be identical, and the pin insertion portion 105 and the connector insertion portion 106 may be formed to be integrated with each other.

Each of the plurality of fixing holes 103 penetrates the housing 81 substantially in the Z direction so as to be open to the lower surface 91 and the upper surface 92. The plurality of fixing holes 103 are arranged in two rows in the Y direction. The two through holes 101 and 102 are located between the plurality of fixing holes 103 forming one row and the plurality of fixing holes 103 forming the other row in the X direction.

The cross section of each of the plurality of fixing holes 103 is smaller than the cross section of the pin insertion portion 105 and is smaller than the cross section of the connector insertion portion 106. In the present embodiment, the cross section of the fixing hole 103 is formed in a square or a perfect circle shape. It is noted that the cross section of the fixing hole 103 is not limited to this example.

The plurality of leads 82 and 83 are made of a conductor such as metal. The plurality of leads 82 and the plurality of leads 83 are adjacent to each other in the X direction and are formed in mirror symmetry with each other. Each of the plurality of leads 82 and 83 includes an external pin 111, an internal pin 112, and a press-fit pin 113. The external pin 111 is an example of a second terminal and an external terminal. The internal pin 112 is an example of a first terminal and an internal terminal. The press-fit pin 113 is an example of a stationary part.

The external pin 111 is located outside the housing 81. Specifically, the external pin 111 is located outside the through holes 101 and 102 and is located at least partially between the housing 81 and the FPC 37. Therefore, the lower surface 91 of the housing 81 faces the external pin 111. It is noted that a part of the external pin 111 may be located inside the housing 81.

The external pin 111 has a base portion 115, a joining portion 116, and an inclined portion 117. The joining portion 116 is an example of a second part. The inclined portion 117 is an example of a third part. The entire base portion 115 is located between the housing 81 and the FPC 37. It is noted that the base portion 115 is not limited to this example.

The base portion 115 includes a first connection portion 115a, a second connection portion 115b, and an intermediate portion 115c. The second connection portion 115b is an example of a first part. The first connection portion 115a and the second connection portion 115b extend substantially in the X direction. That is, the first connection portion 115a and the second connection portion 115b extend along the lower surface 91 of the housing 81.

The first connection portion 115a is closer to the pin insertion portion 105 than the second connection portion 115b. The second connection portion 115b is closer to the cutout 95 and the fixing hole 103 than the first connection portion 115a. Furthermore, the first connection portion 115a is more separated from the lower surface 91 of the housing 81 than the second connection portion 115b. That is, the first connection portion 115a and the second connection portion 115b extend substantially in parallel. The intermediate portion 115c extends obliquely relative to the first connection portion 115a and the second connection portion 115b between one end of the first connection portion 115a and one end of the second connection portion 115b.

The joining portion 116 is more separated from the housing 81 than the second connection portion 115b of the base portion 115. Specifically, the joining portion 116 is more separated from the center of the housing 81 than the second connection portion 115b in the X direction. Further, the joining portion 116 is more separated from the housing 81 than the second connection portion 115b in the Z direction. Further, the joining portion 116 is more separated from the housing 81 than the first connection portion 115a in the Z direction. The joining portion 116 is located at an end portion of the relay connector 66 in the −Z direction.

The joining portion 116 extends substantially in the X direction. Therefore, the joining portion 116 and the first connection portion 115a and the second connection portion 115b of the base portion 115 extend substantially in parallel. The inclined portion 117 is provided between the other end portion of the second connection portion 115b and one end portion of the joining portion 116, and extends obliquely relative to the second connection portion 115b and the joining portion 116.

As illustrated in FIG. 4, in a projection view seen in a direction orthogonal to the upper surface 92 (in the −Z direction in FIG. 4), the external pin 111 extends across the cutout 95. In the projection view, the cutout 95 is located between at least a part of the base portion 115 and at least a part of the joining portion 116.

Furthermore, in the projection view seen in the direction orthogonal to the upper surface 92, the joining portion 116 and the inclined portion 117 are separated from the lower surface 91. In other words, the lower surface 91 does not overlap the joining portion 116 and the inclined portion 117. In the present embodiment, the base portion 115 overlaps the lower surface 91. It is noted that the joining portion 116 and the inclined portion 117 may overlap the lower surface 91.

As illustrated in FIG. 5, the internal pin 112 protrudes substantially in the +Z direction from the other end portion of the first connection portion 115a. In other words, the internal pin 112 and the first connection portion 115a are connected to each other.

The internal pin 112 of the lead 82 is accommodated in the through hole 101 of the housing 81. The internal pin 112 of the lead 83 is accommodated in the through hole 102. The internal pin 112 penetrates the pin insertion portion 105. In the connector insertion portion 106, the internal pin 112 extends along the protrusion 106d. It is noted that the internal pin 112 is not limited to this example.

The press-fit pin 113 protrudes substantially in the +Z direction from the second connection portion 115b. That is, the press-fit pin 113 protrudes from the base portion 115 at a location separated from the internal pin 112. In other words, the press-fit pin 113 is connected to the base portion 115 at a location separated from the internal pin 112.

The internal pin 112 and the press-fit pin 113 protrude substantially in parallel from the base portion 115. In the Z direction, the length of the internal pin 112 protruding from the base portion 115 is larger than the length of the press-fit pin 113 protruding from the base portion 115. It is noted that the lengths of the internal pin 112 and the press-fit pin 113 are not limited to this example.

The press-fit pins 113 of the plurality of leads 82 and 83 are press-fitted into the plurality of fixing holes 103. Accordingly, the press-fit pin 113 is fixed to the housing 81. The leads 82 and 83 are mounted in the housing 81 such that the base portion 115 is separated from the housing 81. It is noted that the base portion 115 may be in contact with the housing 81.

The plurality of leads 82 are arranged at intervals in the Y direction. The Y direction is a direction along the upper surface 92 and is an example of a first direction. The press-fit pins 113 of the plurality of leads 82 are press-fitted into the fixing holes 103 forming one row.

As illustrated in FIG. 4, the internal pins 112 of the plurality of leads 82 are accommodated in one through hole 101. Therefore, the internal pins 112 of the plurality of leads 82 are arranged at intervals in the Y direction inside one through hole 101.

The internal pins 112 of the plurality of leads 82 are surrounded by an edge 105a of the pin insertion portion 105 provided on the lower surface 91. The edge 105a is one endless edge. That is, in the vicinity of the lower surface 91, the pin insertion portion 105 is one hole that is not divided. The internal pins 112 of the plurality of leads 82 extend through the undivided pin insertion portions 105.

The plurality of leads 83 are arranged at intervals in the Y direction. The press-fit pins 113 of the plurality of leads 83 are press-fitted into the fixing holes 103 forming the other row. The internal pins 112 of the plurality of leads 83 are accommodated in one through hole 102.

As illustrated in FIG. 5, the external pins 111 of the plurality of leads 82 and 83 are joined to the plurality of pads 73 by, for example, solder S. As a result, the relay connector 66 is mounted on the FPC 37. The external pin 111 is electrically connected to, for example, the preamplifier 65 via the wiring of the FPC 37.

The connector provided on the bottom wall 25 is connected to the relay connector 66 to bring the terminal into contact with the internal pin 112. As a result, the relay connector 66 is electrically connected to the relay connector 53 mounted on the PCB 17 via the connector provided on the bottom wall 25.

Hereinafter, a part of a method of mounting the relay connector 66 on the FPC 37 will be exemplified. It is noted that the method of mounting the relay connector 66 on the FPC 37 is not limited to the following method, and other methods may be used. First, solder paste (solder S) is supplied to the pad 73 by, for example, printing or coating. Further, the relay connector 66 is mounted on the pad 73.

Next, the FPC 37 is heated in a reflow furnace, and the solder paste is melted. As a result, the joining portion 116 of the relay connector 66 is joined to the pad 73. At this time, flux mixed or separately supplied to the solder S may flow out of the solder S.

Next, the FPC 37 and the relay connector 66 are cleaned by, for example, ultrasonic cleaning. For example, the FPC 37 is placed in a tank filled with cleaning liquid C. As indicated by an arrow in FIG. 5, the cleaning liquid C flows into, for example, a gap G between the FPC 37 and the housing 81.

The external pin 111 is located outside the housing 81 and is interposed between the FPC 37 and the housing 81. Therefore, the external pin 111 expands the gap G between the FPC 37 and the housing 81. The cleaning liquid C can smoothly flow through the gap G.

The cutout 95 exposes the external pin 111 to a greater extent. Therefore, a larger portion of the external pin 111 is exposed to the cleaning liquid C. Furthermore, the cutout 95 promotes the cleaning liquid C to flow into the gap G.

Furthermore, the cutout 95 prevents from formation of a narrow wedge-shaped gap between the housing 81 and the inclined portion 117. In general, flux approaches the housing 81 along the joining portion 116 and the inclined portion 117 due to, for example, surface tension. In other words, the flux crawls up the inclined portion 117. The flux that has entered the wedge-shaped gap is difficult to remove. However, in the present embodiment, since the formation of the wedge-shaped gap is prevented, the flux is prevented from remaining.

The cleaning liquid C flows into the through holes 101 and 102 from the pin insertion portion 105. The pin insertion portion 105 is formed to be large so as to accommodate the internal pins 112 of the plurality of leads 82 or the plurality of leads 83. Therefore, the cleaning liquid C can smoothly flow into the through holes 101 and 102.

A substance that may contaminate the HDD 10, such as flux, may be present inside the through holes 101 and 102 or adhere to the internal pin 112. However, the cleaning liquid C smoothly flowing through the through holes 101 and 102 can more reliably remove the substance. The cleaning liquid C which has cleaned the inside of the housing 81 is discharged to the outside of the housing 81 from, for example, the connector insertion portion 106.

The cleaning liquid C may be discharged from the gap G through the FPC 37 and the holes 75 and 76 of the reinforcing plate 67. The flow of the cleaning liquid C is not limited to the above description and the arrows in FIGS. 3 and 5. For example, the cleaning liquid C may flow into the through holes 101 and 102 from the connector insertion portion 106, or may flow into the gap G from the holes 75 and 76.

When ultrasonic cleaning is completed, the FPC 37 is taken out from the cleaning liquid C. At this time, the cleaning liquid C is discharged through at least one of the gap G, the through holes 101 and 102, and the holes 75 and 76.

For example, the cleaning liquid C transmits ultrasonic waves. The ultrasonic waves adhere to the leads 82 and 83 or float flux existing inside the housing 81. Thereafter, the cleaning liquid C is discharged together with the flux as described above. As described above, the mounting of the relay connector 66 on the FPC 37 is completed.

In the HDD 10 according to the first embodiment described above, the housing 81 has the lower surface 91 and the upper surface 92 opposite the lower surface 91. The housing 81 is provided with the through hole 101 that is open to the lower surface 91 and the upper surface 92. Each of the plurality of leads 82 includes the internal pin 112 accommodated in the through hole 101. Thus, the internal pins 112 of the plurality of leads 82 are accommodated in the one through hole 101. As a result, the through hole 101 has a larger cross-sectional area than the one accommodating the internal pin 112 of one lead 82. This allows the cleaning liquid C to more smoothly flow through the through hole 101 to clean the relay connector 66 attached to the FPC 37 with the lower surface 91 facing the FPC 37, for example. The cleaning liquid C is not hindered from flowing through the through hole 101, therefore, the cleaning liquid C can more properly clean the inside of the through hole 101, the gap between the lead 82 and the housing 81, and the gap G between the FPC 37 and the housing 81, for example. As such, the relay connector 66 of the present embodiment can be avoided from being contaminated inside or in the gap G between the FPC 37 and the housing 81 by a substance such as remnant flux.

The HDD 10 of the present embodiment is a large-capacity HDD including ten or more magnetic disks 12. The inside of the case 11 is airtightly sealed and filled with a gas different from air, such as helium. Contaminants such as flux inside the case 11 of such an HDD 10, if any, may hinder the operation of the magnetic heads 48. However, the HDD 10 according to the present embodiment can be avoided from being internally contaminated with sureness, thereby preventing hindrance to the operation of the magnetic heads 48.

Each of the plurality of leads 82 includes the external pin 111 outside the through hole 101. The external pin 111 is connected to the internal pin 112. The lower surface 91 faces the external pins 111. Thus, the external pins 111 are interposed between the housing 81 and the FPC 37 on which the relay connector 66 is mounted. Because of this, the housing 81 is more spaced from the FPC 37 than the housing 81 having embedded external pins 111. This accordingly enlarges the gap G between the housing 81 and the FPC 37, allowing the cleaning liquid C to more properly clean the gap G. For example, the cleaning liquid C can clean even the lower surface 91 with irregularities thoroughly.

The housing 81 has the side surface 93 facing the X direction different from the −Z direction that the lower surface 91 faces. The housing 81 is provided with the cutout 95 at the corner between the lower surface 91 and the side surface 93. The external pin 111 extends across the cutout 95 in a projection view seen in the Z direction orthogonal to the upper surface 92. As a result, the external pin 111 is exposed more greatly than when the housing 81 is provided with no cutout 95. In other words, the gap between the external pin 111 and the housing 81, in which a substance such as flux is likely to remain, decreases. Furthermore, the housing 81 with the cutout 95 can allow the cleaning liquid C to easily enter the gap G between the housing 81 and the FPC 37 for cleaning the relay connector 66, as compared with the housing 81 without the cutout 95. In this manner, the relay connector 66 of the present embodiment can be avoided from being contaminated with sureness.

The external pin 111 includes the second connecting part 115b, the joining part 116, and the inclined part 117. The second connecting part 115b extends along the lower surface 91. The joining part 116 is spaced further from the housing 81 than the second connecting part 115b. The inclined part 117 extends obliquely relative to the second connecting part 115b between the second connecting part 115b and the joining part 116. The joining part 116 and the inclined part 117 are spaced from the lower surface 91 in a projection view seen in the Z direction orthogonal to the upper surface 92. For example, the obliquely extending, inclined part 117 may overlap the lower surface 91. In such a case a tapered gap may occur between the inclined part 117 and the lower surface 91, in which a substance such as flux is likely to be accumulated. However, in the relay connector 66 of the present embodiment, due to the inclined part 117 being away from the lower surface 91, such a gap is unlikely to occur, more surely avoiding the relay connector 66 from being contaminated by the substance such as flux. In addition, the flux generally may run up the obliquely extending inclined part 117g. However, the housing 81 is spaced from the inclined part 117 by the cutout 95. As such, the relay connector 66 of the present embodiment can be avoided from contamination by the flux with sureness since the flux is prevented from entering the housing 81.

The external pin 111 is spaced from the housing 81. In other words, there is a larger gap between the external pin 111 and the housing 81, so that the cleaning liquid C can easily flow through the larger gap. In addition, the distance between the housing 81 and the FPC 37 to which the external pin 111 is joined increases. This allows the cleaning liquid C to more smoothly flow through the gap G between the housing 81 and the FPC 37, to be able to clean the relay connector 66 thoroughly.

The FPC 37 includes the mounting surface 71 facing the lower surface 91 and a plurality of pads 73 mounted on the mounting surface 71 and connected to the plurality of leads 82. As such, to clean the relay connector 66 mounted on the FPC 37 with the cleaning liquid C, the cleaning liquid C can more smoothly flow through the through hole 101 as described above. The HDD 10 according to the present embodiment can prevent the relay connector 66 from being contaminated inside or in the gap G between the FPC 37 and the housing 81 by a substance such as remnant flux, for example.

### Second Embodiment

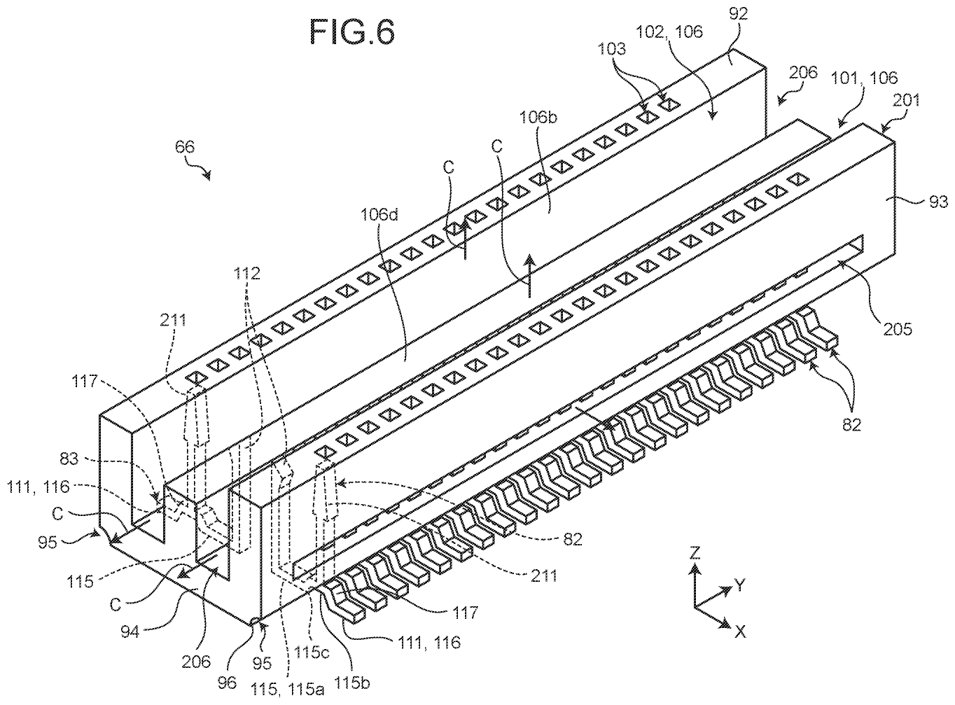

Hereinafter, a second embodiment will be described with reference to FIGS. 6 to 8. It is noted that in the following description of the plurality of embodiments, components having functions similar to those of components already described are denoted by the same reference numerals as those of the components already described, and the description thereof may be omitted. In addition, the plurality of components denoted by the same reference numerals do not necessarily have all the functions and properties in common, and may have different functions and properties according to each embodiment.

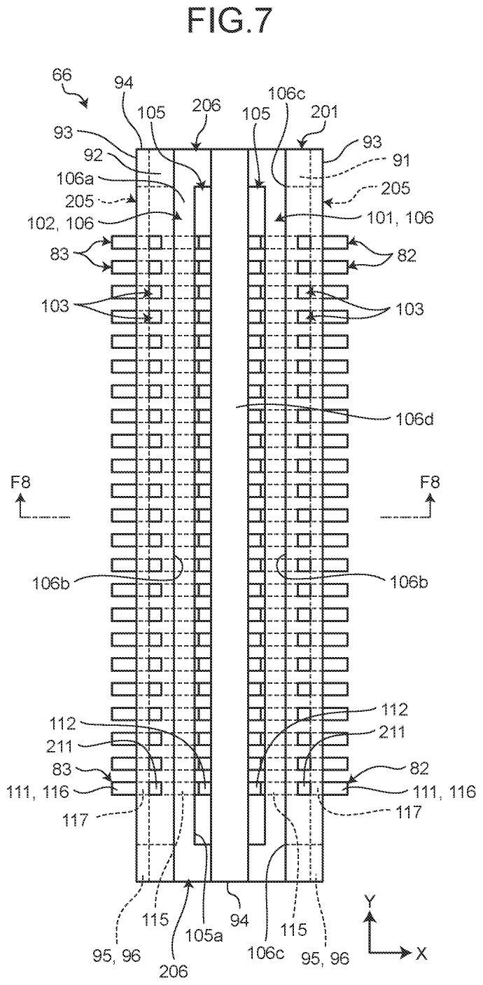

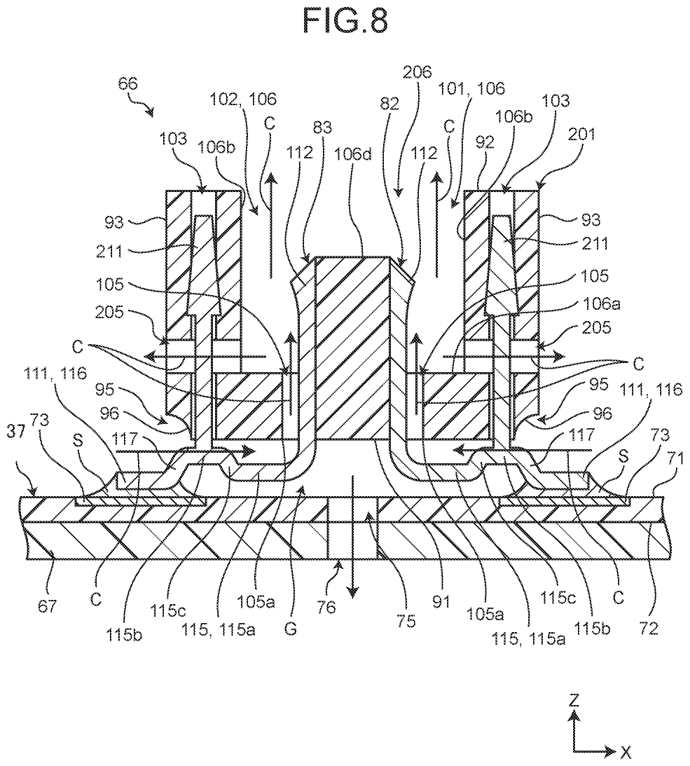

FIG. 6 is an exemplary perspective view illustrating the relay connector 66 according to the second embodiment. FIG. 7 is an exemplary plan view illustrating the relay connector 66 of the second embodiment. FIG. 8 is an exemplary cross-sectional view of the FPC 37 and the relay connector 66 of the second embodiment taken along line F8-F8 in FIG. 7.

As illustrated in FIG. 8, the relay connector 66 of the second embodiment includes a housing 201 instead of the housing 81. The housing 201 is substantially equal to the housing 81, except as described below.

Two first branch holes 205 and two second branch holes 206 are provided in the housing 201. It is noted that one of the first branch hole 205 and the second branch hole 206 may be provided in the housing 201. The number of the first branch holes 205 and the second branch holes 206 is not limited to this example.

The one first branch hole 205 is open to the one side surface 93 and the one inner side surface 106b and communicates with the connector insertion portion 106 of the through hole 101. The other first branch hole 205 is open to the other side surface 93 and the other inner side surface 106b and communicates with the connector insertion portion 106 of the through hole 102. That is, the first branch hole 205 communicates with the outside of the housing 81 at a location farther away from the FPC 37 than the lower surface 91.

Each of the two first branch holes 205 extends in the Y direction. In the Y direction, a length of the first branch hole 205 is larger than a length of a row formed by a plurality of leads 202. It is noted that the dimension of the first branch hole 205 is not limited to this example.

The first branch hole 205 is separated from the lower surface 91, the upper surface 92, and the cutout 95. The first branch hole 205 communicates with the plurality of fixing holes 103. It is noted that the first branch hole 205 may be separated from the fixing hole 103.

As illustrated in FIG. 7, the one second branch hole 206 is open to the one end surface 94 and the one inner end surface 106c and communicates with the connector insertion portion 106 of the through holes 101 and 102. The other second branch hole 206 is open to the other end surface 94 and the other inner end surface 106c and communicates with the connector insertion portion 106 of the through holes 101 and 102.

In the second embodiment, the protrusion 106d is connected to the inner end surface 106c. Further, the cross section of the second branch hole 206 is substantially equal to the cross section of the connector insertion portion 106 of the through holes 101 and 102. Therefore, the second branch hole 206 is integrated with the connector insertion portion 106. According to another expression, the through holes 101 and 102 of the second embodiment are also open to the end surface 94. It is noted that the cross section of the second branch hole 206 may be different from the cross section of the connector insertion portion 106.

As illustrated in FIG. 8, in the second embodiment, each of the plurality of leads 82 and 83 includes a press-fit pin 211 instead of the press-fit pin 113. The press-fit pin 211 is substantially equal to the press-fit pin 113, except as described below.

In the Z direction, the length of the press-fit pin 211 protruding from the base portion 115 is longer than the length of the internal pin 112 protruding from the base portion 115. The tip of the press-fit pin 211 is located inside the fixing hole 103.

The press-fit pins 211 of the plurality of leads 82 and 83 pass through the first branch hole 205 substantially in the Z direction. In other words, some of the press-fit pins 211 of the plurality of leads 82 are arranged in the Y direction at intervals in one first branch hole 205. Further, some of the press-fit pins 211 of the plurality of leads 83 are arranged in the Y direction at intervals in the other first branch hole 205. It is noted that, when the leads 82 and 83 have the press-fit pin 113, the press-fit pin 113 may be separated from the first branch hole 205.

When the FPC 37 and the relay connector 66 are ultrasonically cleaned, a part of the cleaning liquid C is discharged from the through holes 101 and 102 through the first branch hole 205. Further, another part of the cleaning liquid C is discharged from the through holes 101 and 102 through the second branch hole 206. It is noted that a flow of the cleaning liquid C is not limited to this example.

In the HDD 10 of the second embodiment described above, the plurality of leads 82 are aligned with each other in the Y direction along the upper surface 92. The housing 201 has the side surface 93 extending between the lower surface 91 and the upper surface 92 in the Y direction. The housing 201 is provided with the first branch hole 205 that opens to the side surface 93 and communicates with the through hole 101. This allows the cleaning liquid C to flow through the first branch hole 205 and the through hole 101, therefore, the cleaning liquid C can more properly clean the relay connector 66. Therefore, the relay connector 66 of the present embodiment can be avoid from being contaminated with sureness.

Each of the plurality of leads 82 has the press-fit pin 211. The press-fit pin 211 is connected to the external pin 111 and is fixed to the housing 201 apart from the internal pin 112. In the Z direction in which the upper surface 92 faces, the press-fit pin 211 is larger in length than the internal pin 112. Therefore, the housing 201 is easily fixed to the press-fit pin 211 more apart from the external pin 111 than when the press-fit pin 211 is short. As a result, when the external pin 111 is joined to the FPC 37, a distance between the housing 201 and the FPC 37 increases. As described above, the cleaning liquid C can more smoothly flow through the gap G between the housing 201 and the FPC 37, therefore, the cleaning liquid C can more properly clean the relay connector 66.

The plurality of leads 82 are aligned with each other in the Y direction along the upper surface 92. The housing 201 has the end surface 94 at an end in the Y direction. The housing 201 is provided with the second branch hole 206 that opens to the end surface 94 and communicates with the through hole 101. As a result, the cleaning liquid C can flow through the second branch hole 206 and the through hole 101, therefore, the cleaning liquid C can more properly clean the relay connector 66. The relay connector 66 of the present embodiment can be avoided from being contaminated with sureness.

### Third Embodiment

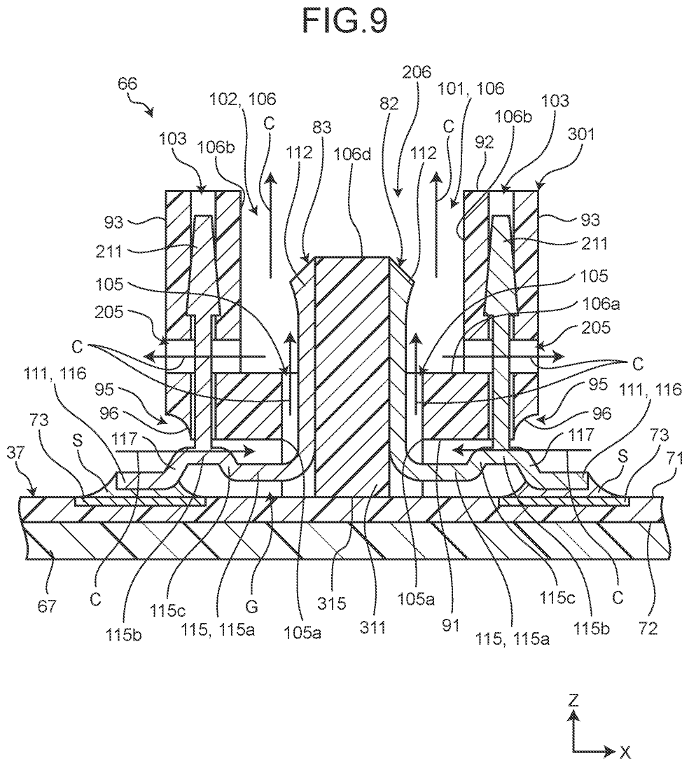

Hereinafter, a third embodiment will be described with reference to FIG. 9. FIG. 9 is an exemplary cross-sectional view illustrating the FPC 37 and the relay connector 66 according to the third embodiment. As illustrated in FIG. 9, the relay connector 66 of the third embodiment includes a housing 301 instead of the housing 201. The housing 301 is substantially equal to the housing 201, except as described below.

The housing 301 further includes a protruding portion 311. The protruding portion 311 protrudes substantially in the Z direction from the lower surface 91. In the X direction, at least a part of the protruding portion 311 is located between the plurality of leads 82 and the plurality of leads 83.

The protruding portion 311 has a lower end surface 315. The lower end surface 315 is an example of a sixth surface. The lower end surface 315 is provided at an end portion of the protruding portion 311 in the −Z direction. In the present embodiment, the lower end surface 315 is located at an end portion of the housing 81 in the −Z direction.

The lower end surface 315 is formed to be substantially flat and faces substantially in the −Z direction. The lower end surface 315 is at least partially in contact with the mounting surface 71 of the FPC 37. On the other hand, the lower surface 91 is more separated from the FPC 37 than the lower end surface 315.

In the HDD 10 of the third embodiment described above, the housing 301 has the lower end surface 315 in contact with the FPC 37. The lower surface 91 is spaced further from the FPC 37 than the lower end surface 315. That is, the through hole 101 opening to the lower surface 91 is not closed by the FPC 37. Therefore, the cleaning liquid C can flow through the through hole 101 more smoothly.

### Fourth Embodiment

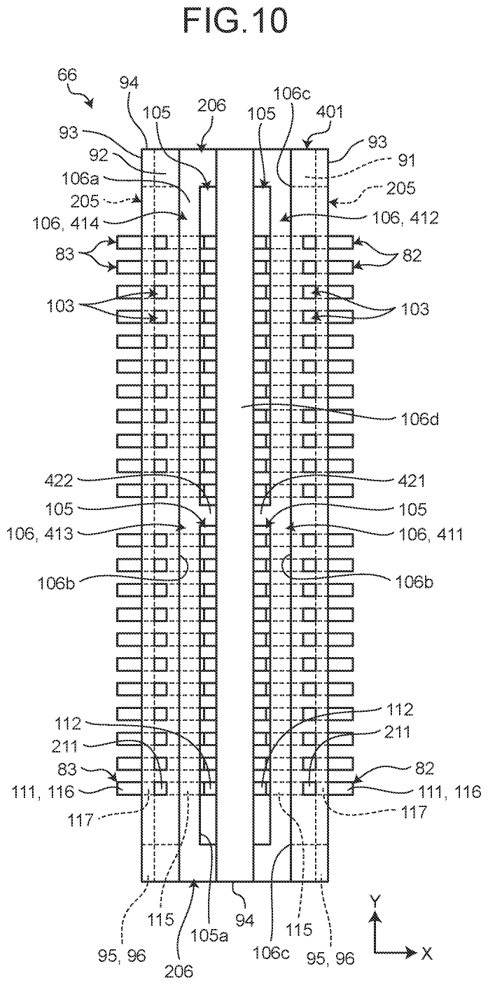

Hereinafter, a fourth embodiment will be described with reference to FIG. 10. FIG. 10 is an exemplary plan view illustrating the relay connector 66 according to the fourth embodiment. As illustrated in FIG. 10, the relay connector 66 of the fourth embodiment includes a housing 401 instead of the housing 201. The housing 401 is substantially equal to the housing 201, except as described below.

The housing 401 is provided with four through holes 411, 412, 413, and 414 instead of the two through holes 101 and 102. The through hole 411 is an example of the through hole. The through holes 411, 412, 413, and 414 are substantially equal to the through holes 101 and 102, except as described below.

The through holes 411 and 412 are arranged at intervals in the Y direction. The through holes 413 and 414 are also arranged at intervals in the Y direction. The through holes 411 and 412 and the through holes 413 and 414 are adjacent to each other in the X direction, and are formed in mirror symmetry with each other.

The housing 401 further includes two ribs 421 and 422. The rib 421 is provided between the pin insertion portion 105 of the through hole 411 and the pin insertion portion 105 of the through hole 412. That is, the rib 421 separates the pin insertion portion 105 of the through hole 411 and the pin insertion portion 105 of the through hole 412 from each other.

The connector insertion portion 106 of the through hole 411 and the connector insertion portion 106 of the through hole 412 communicate with each other. It is noted that the rib 421 may separate the connector insertion portion 106 of the through hole 411 and the connector insertion portion 106 of the through hole 412 from each other.

The rib 422 is provided between the pin insertion portion 105 of the through hole 413 and the pin insertion portion 105 of the through hole 414. The rib 422 separates the pin insertion portion 105 of the through hole 413 and the pin insertion portion 105 of the through hole 414 from each other.

The connector insertion portion 106 of the through hole 413 and the connector insertion portion 106 of the through hole 414 communicate with each other. It is noted that the rib 422 may separate the connector insertion portion 106 of the through hole 413 and the connector insertion portion 106 of the through hole 414 from each other.

Half of the plurality of leads 82 are accommodated in the through hole 411. The remaining half of the plurality of leads 82 are accommodated in the through hole 412. Half of the plurality of leads 83 are accommodated in the through hole 413. The remaining half of the plurality of leads 83 are accommodated in the through hole 414. It is noted that the number of leads 82 and 83 accommodated in the through holes 411, 412, 413, and 414 is not limited to this example.

In the HDD 10 of the fourth embodiment described above, the two through holes 411 and 412 are aligned with each other in the Y direction. The internal pins 112 of the plurality of leads 82 are accommodated in the through hole 411. The internal pins 112 of the other plurality of leads 82 are accommodated in the through hole 412. The housing 401 has the rib 421 that separates the two through holes 411 and 412 from each other. As a result, the housing 401 is improved in strength.

### Fifth Embodiment

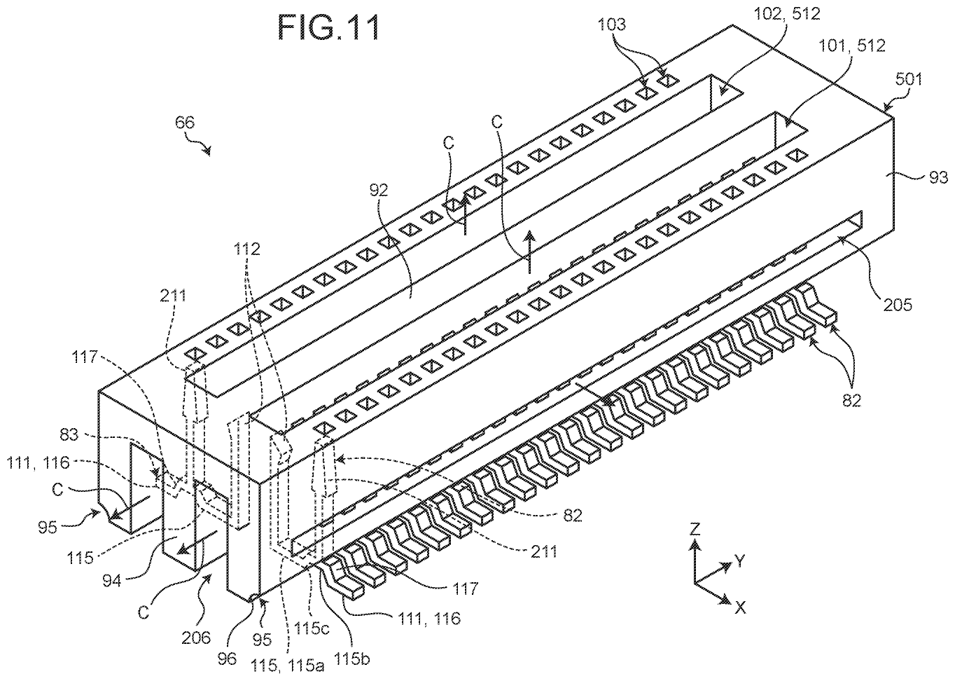

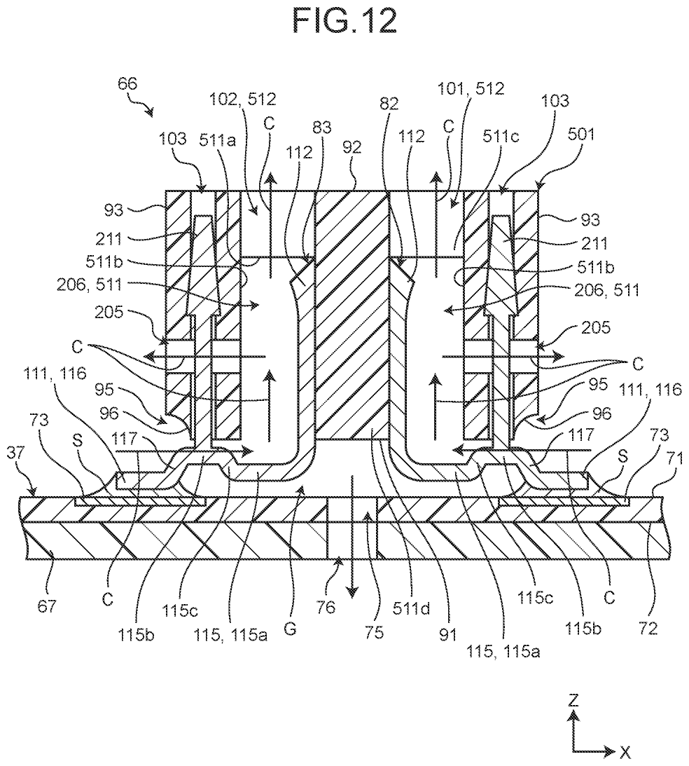

Hereinafter, a fifth embodiment will be described with reference to FIGS. 11 and 12. FIG. 11 is an exemplary perspective view illustrating the relay connector 66 according to the fifth embodiment. FIG. 12 is an exemplary cross-sectional view illustrating the relay connector 66 of the fifth embodiment.

The relay connector 66 of the fifth embodiment includes a housing 501 instead of the housing 201. The housing 501 is substantially equal to the housing 201, except as described below.

Each of the through holes 101 and 102 provided in the housing 501 includes a pin insertion portion 511 and a connector insertion portion 512 instead of the pin insertion portion 105 and the connector insertion portion 106. The pin insertion portion 511 and the connector insertion portion 512 are substantially equal to the pin insertion portion 105 and the connector insertion portion 106, except as described below.

The housing 501 further includes a bottom surface 511a, two inner side surfaces 511b, two inner end surfaces 511c, and a protrusion 511d instead of the bottom surface 106a, the inner side surface 106b, the inner end surface 106c, and the protrusion 106d. The bottom surface 511a, the inner side surface 511b, the inner end surface 511c, and the protrusion 511d are substantially equal to the bottom surface 106a, the inner side surface 106b, the inner end surface 106c, and the protrusion 106d, except as described below.

The bottom surface 511a is provided at an end portion of the pin insertion portion 511 in the +Z direction. The bottom surface 511a is located between the lower surface 91 and the upper surface 92 in the Z direction. The bottom surface 511a is formed to be substantially flat and faces substantially in the −Z direction.

The two inner side surfaces 511b extend substantially in the −Z direction from the opposite ends of the bottom surface 511a in the X direction. The two inner end surfaces 511c extend substantially in the −Z direction from the opposite ends of the bottom surface 511a in the Y direction.

The protrusion 511d protrudes substantially in the −Z direction from the bottom surface 511a at a location separated from the two inner side surfaces 511b. The protrusion 511d is connected to the inner end surface 511c. An end portion of the protrusion 511d in the −Z direction forms a part of the lower surface 91.

The pin insertion portion 511 of the through hole 101 is formed (regulation, section) by the bottom surface 511a, one inner side surface 511b, and the protrusion 511d. The connector insertion portion 512 of the through hole 102 is formed by the bottom surface 511a, the other inner side surface 511b, and the protrusion 511d.

The pin insertion portions 511 of the two through holes 101 and 102 are separated from each other by the protrusion 511d. Further, the connector insertion portions 512 of the two through holes 101 and 102 are separated from each other.

The connector insertion portion 512 is open to the bottom surface 512a. The cross-sectional area of the connector insertion portion 512 that is open to the bottom surface 512a is substantially equal to that of the bottom surface 512a. It is noted that the cross-sectional area of the connector insertion portion 512 and the size of the bottom surface 512a may be different.

The first branch hole 205 is open to the inner side surface 511b and communicates with the pin insertion portion 511. The second branch hole 206 is open to the inner end surface 511c and communicates with the pin insertion portion 511. The cross section of the second branch hole 206 is substantially equal to the cross section of the pin insertion portion 511. Therefore, the second branch hole 206 is integrated with the pin insertion portion 511.

The internal pin 112 is accommodated in the pin insertion portion 511. In the pin insertion portion 511, the internal pin 112 extends along the protrusion 511d. The terminal of the connector provided on the bottom wall 25 passes through the connector insertion portion 512 and contacts the internal pin 112 of the pin insertion portion 511. It is noted that the internal pin 112 may be partially accommodated in the connector insertion portion 512.

In the housing 501, the area of the substantially flat upper surface 92 is larger than the area of the substantially flat lower surface 91. Therefore, when the relay connector 66 is mounted on the pad 73, a mounter can easily suction and hold the upper surface 92.

In the HDD 10 according to the fifth embodiment described above, the area of the flat upper surface 92 is larger than the area of the flat lower surface 91. As a result, the relay connector 66 can be easily held when mounted on the FPC 37.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A connector comprising:
a housing having a first surface and a second surface opposite the first surface, the housing being provided with a through hole opening to the first surface and the second surface; and
a plurality of leads each of which includes a first terminal accommodated in the through hole.

2. The connector according to claim 1, wherein
the plurality of leads are aligned with each other in a first direction along the second surface,
the housing has a third surface extending between the first surface and the second surface in the first direction, and
the housing is provided with a first branch hole opening to the third surface and communicating with the through hole.

3. The connector according to claim 1, wherein
each of the plurality of leads includes a second terminal outside the through hole, the second terminal being connected to the first terminal, and
the first surface faces the second terminal.

4. The connector according to claim 3, wherein
the housing has a fourth surface facing a direction different from a direction which the first surface faces,
the housing is provided with a cutout at a corner between the first surface and the fourth surface, and
the second terminal extends across the cutout in a projection view seen in a direction orthogonal to the second surface.

5. The connector according to claim 4, wherein
the second terminal includes:
a first part extending along the first surface;
a second part being spaced further from the housing than the first part; and
a third part extending obliquely relative to the first part between the first part and the second part, and
the second part and the third part are spaced from the first surface in the projection view seen in the direction orthogonal to the second surface.

6. The connector according to claim 3, wherein
each of the plurality of leads includes a stationary part fixed to the housing and connected to the second terminal apart from the first terminal, and
the stationary part is larger in length than the first terminal in a direction which the second surface faces.

7. The connector according to claim 3, wherein
the second terminal is spaced from the housing.

8. The connector according to claim 1, wherein
the plurality of leads are aligned with each other in a first direction along the second surface,
the housing has a fifth surface at an end in the first direction, and
the housing is provided with a second branch hole opening to the fifth surface and communicating with the through hole.

9. A disk device comprising:
the connector according to claim 1; and
a substrate including
a mounting surface facing the first surface, and
a plurality of pads on the mounting surface joined to the plurality of leads.

10. The disk device according to claim 9, wherein
the housing has a sixth surface in contact with the substrate, and
the first surface is spaced further from the substrate than the sixth surface.

11. A connector comprising:
a housing; and
a plurality of leads each of which includes
an external terminal outside the housing,
an internal terminal protruding from the external terminal to be accommodated in the housing, and
a stationary part being fixed to the housing and protruding from the external terminal apart from the internal terminal, wherein
the stationary part protruding from the external terminal is larger in length than the internal terminal protruding from the external terminal.
